(19) United States
(12) Patent Application Publication
(10) Pub. No.: US 2005/0001608 A1
(43) Pub. Date: Jan. 6, 2005

(54) Phase shift circuit application for DVD ROM chipset in HTOL board design

(76) Inventors: Brian Peng, Hsin-Tien City (TW); Michael Tsai, Hsin-Tien City (TW)

Correspondence Address: J C PATENTS, INC., 4 VENTURE, SUITE 250, IRVINE, CA, 92618, US

(21) Appl. No.: 10/656,006

(22) Filed: Sep. 4, 2003

(30) Foreign Application Priority Data
Jul. 4, 2003 (TW) 92118296

(51) Int. Cl. G01R 23/165

(52) U.S. Cl. 324/76.29

(57) ABSTRACT

A board for testing DVD (Digital Versatile Disc) ROM (Read Only Memory) chip-set and associated circuit for generating radio frequency signals with phase difference are provided. The circuit includes signal potential dividers, high pass filters, and a phase shifter. The circuit receives a digital input signal, which has a predetermined frequency, generated by a chip test device. The radio frequency signals with phase difference for testing the analog circuit block of DVD ROM chipset are generated according to the received digital input signal. Therefor, the high temperature operating life test for optical disc drive chips can be achieved.

### CROSS-REFERENCE TO RELATED APPLICATION

This application claims the priority benefit of Taiwan application serial no. 92118296, filed Jul. 4, 2003.

### BACKGROUND OF THE INVENTION

1. Field of Invention

The present invention relates to a testing board and its associated circuit. More particularly, the present invention relates to a phase shift Radio Frequency (RF) signal generating circuit for DVD ROM (Digital Versatile Disc Read Only Memory) chipset in HTOL (High Temperature Operating Life) board design.

2. Description of Related Art

Storage media has always played one of the leading roles in computer system. Significant researches are invested in storage media on variety as well as stability and high capacity. Novelties of DVD ROM are invented and manufactured as the application is highly popularized.

Generally, the driving circuit of DVD ROM is manufactured as a DVD ROM chipset in order to lower chip size and cost. For testing purpose, a DVD chipset is plugged on a testing board, and placed in testing chamber of an ambient temperature about 125° C. with proper connection to testing signal device in order to machine-test High Temperature Operating Life (HTOL).

In a testing device that is similar to HTOL test , the testing signals are mostly digital, which is not appropriate for a pick up head requiring peak-to-peak 75 mV signal swing in a Digital Versatile Disc (DVD). The reason is a DVD chipset usually suffers from phase difference between a plurality of phase-shift RF signals, thus the testing process is more difficult.

### SUMMARY OF THE INVENTION

According to foregoing reasons, this invention provides a phase-shift RF signal generating circuit on a DVD ROM chipset test board in order to apply HTOL test so as to evaluate reliability of a DVD ROM chipset in this present invention.

As embodied and broadly described herein, the invention provides a phase-shift RF signal generator on a DVD ROM chipset testing board, which applies to HTOL test for DVD ROM chipset in order to evaluate reliability of which. Wherein, the DVD ROM chipset test board comprises a testing base and a phase-shift RF-signal generating circuit. The testing board has at least one chip socket to accommodate Device Under Test (DUT) chipset, and a connector to adapt a testing device. The testing device providing a frequency-variant digital input signal. As to the phase-shift RF-signal generating circuit, it is for generating first, second, third, and fourth phase-shift RF-signals for testing DVD chipset, where the first and the second phase-shift RF signals are in phase, and have a phase difference to the third and the fourth phase-shift RF-signals.

In one preferred embodiment, the phase-shift RF-signal generating circuit on the DVD chipset testing board comprises a first signal potential divider, a first high pass filter, a second high pass filter, a phase shifter, a second signal potential divider, a third high pass filter, and a fourth high pass filter.

Where the first signal potential divider is for receiving digital signals provided by testing device, and dividing voltage for output. The first high pass filter couples to the first signal potential divider to eliminate dc signal of the divided input signal so as to generate a first phase-shift RF signal. The second high pass filter as well couples to the first signal potential divider to eliminate dc signal of the divided input signal so as to generate a second phase-shift RF signal. The phase shifter is to receive the digital input signal provided by testing device, and to shift the digital input signal by a phase for output. The second signal potential divider couples to the phase shifter, in order to receive and to divide voltage of the shifted digital input signal for output. The third high pass filter couples to the second signal potential divider to eliminate dc signal of the shifted and divided digital input signal, so as to generate the third phase-shift RF signal. The fourth high pass filter couples to the second signal potential divider to eliminate dc signal of the shifted and divided digital input signal, so as to generate the fourth phase-shift RF signal.

In this preferred embodiment, each the first and the second signal potential divider of this phase-shift RF-signal generating circuit is composed of two resistors in series.

In this preferred embodiment, each the first, second, third, and fourth high pass filter of this phase-shift RF-signal generating circuit comprises a capacitor.

In this preferred embodiment, the phase shifter of the phase-shift RF signal generating circuit comprises an operating amplifier, a first resistor, a capacitor, a second resistor, and a third resistor. Wherein the operating amplifier comprises a positive input terminal, a negative input terminal and an output terminal, and the output terminal is to output phase-shifted digital input signal. One end of the first resistor couples to the digital input signal, and the other end couples to the positive input terminal of the operating amplifier. One end of the capacitor couples to the positive input terminal of the operating amplifier, and the other end couples to ground. One end of the second resistor couples to the digital input signal, and the other end couples to the negative input terminal of the operating amplifier. One end of the third resistor couples to the negative terminal of the operating amplifier, and the other end couples to the output terminal of the operating amplifier.

In the preferred embodiment, the second and the third resistor of the phase-shift RF-signal generator circuit possess identical resistance value.

In the preferred embodiment, the voltage gain of the phase shifter of the phase-shift RF-signal generating circuit is ONE, and the phase shifts by 40°.

In the preferred embodiment, the phase-shift RF-signal generating circuit generates the first, second, third and fourth phase-shift RF signals based on digital input signals provided by testing device, where the phase-shift RF signals possess a signal swing of 75 mV and a frequency of 5 MHz.

The present invention provides another method of generating phase-shift RF signals, which applies to generate a first, second, third, and fourth phase-shift RF signals based on a frequency-variant digital input signal for testing DVD chipset. The method of generating phase-shift RF-signal comprises the following steps. Firstly, receive the digital input signal, and divide voltage of the input signal for output. Secondly, eliminate dc signal of the digital input signal so as to generate the first phase-shift RF signal and the second phase-shift RF signal. Lastly, eliminate dc signal of the shifted and divided digital input signal so as to generate the third and the fourth phase-shift RF signals.

Wherein the method, the phase is shifted by 40°, and each of the first, second, third and fourth phase-shift RF signals possess signal swing of 75 mV and frequency of 5 MHz.

According to the foregoing explanation, the present invention provides a phase-shift RF-signal generating circuit which applies to a DVD chipset testing board so as to implement HTOL testing for DVD chipset.

These and other objects, features and advantages of the present invention will become apparent from the following detailed description of illustrative embodiments thereof, which is to be read in connection with the accompanying drawings.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a DVD ROM chipset according to one preferred embodiment of the present invention.

FIG. 2 illustrates the waveforms of phase-shift RF signals of phase-shift RF-signal generator according to one preferred embodiment of this invention.

FIG. 3 illustrates the circuit of the phase-shift RF-signal generator according to one preferred embodiment of this invention.

FIG. 4 illustrates the frequency response analysis diagram of the phase-shift RF-signal generator according to one preferred embodiment of this invention.

FIG. 5 illustrates the diagram of the DVD ROM HTOL board in one preferred embodiment of this invention.

FIG. 6 illustrates the measurement of the input waveforms of the phase-shift RF-signal generator according to one preferred embodiment of this invention.

FIG. 7 illustrates the output waveforms when the first phase-shift RF signal and the second phase-shift RF signal lead.

FIG. 8 illustrates the output waveforms when the first phase-shift RF signal and the second phase-shift RF signal lag.

### DESCRIPTION OF THE PREFERRED EMBODIMENTS

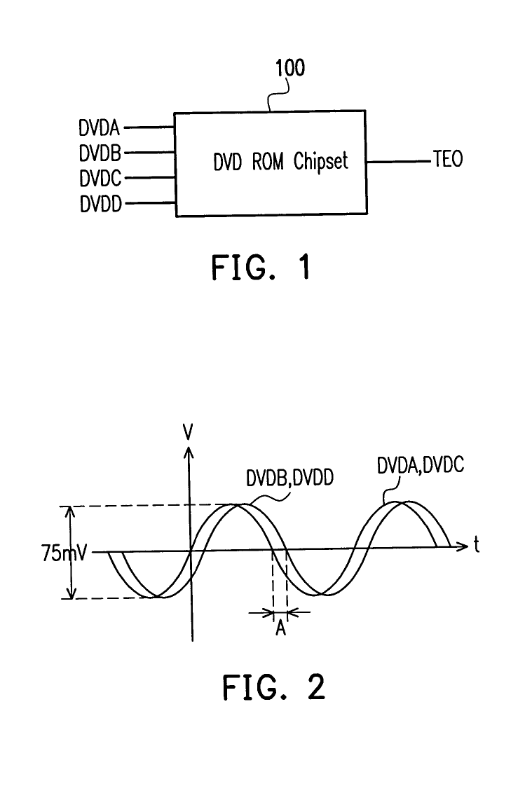

Referring to FIG. 1, a connecting diagram for testing the analog circuit of a DVD ROM chipset is shown. As depicted in FIG. 1, a 75 mV signal swing of each the first, the second, the third, the fourth phase-shift RF signals output from optical pick-up head has to be simulated for testing the analog circuit of a DVD ROM chipset .

The first phase-shift RF signal DVDA and the second phase-shift RF signal DVDC are in phase, and the third phase-shift RF signal DVDB and the fourth phase-shift RF signal DVDD are as well in phase therein. Also, there is a phase difference between the two pairs of the in-phase signals, that is the pair of the signals DVDA and DVDC and the pair of the signals DVDB and DVDD, where the phase difference is shown in FIG. 2.

The analog circuit of the DVD ROM chipset 100 generates an output signal TEO according to the phase difference A in between. When the first phase-shift RF signal DVDA and the second phase-shift RF signal DVDC lead the third phase-shift RF signal DVDB and the fourth phase-shift RF signal DVDD as depicted in FIG. 2, the output voltage of signal TEO is between 1.5 V and 2.1 V. On the contrary, when the first phase-shift RF signal DVDA and the second phase-shift RF signal DVDC lag the third phase-shift RF signal DVDB and the fourth phase-shift RF signal DVDD, the output voltage of signal TEO is between 0.8 V and 1.5 V. Therefore, measuring the output signal TEO is valid to diagnose if the analog circuit of DVD ROM chipset 100 is working properly.

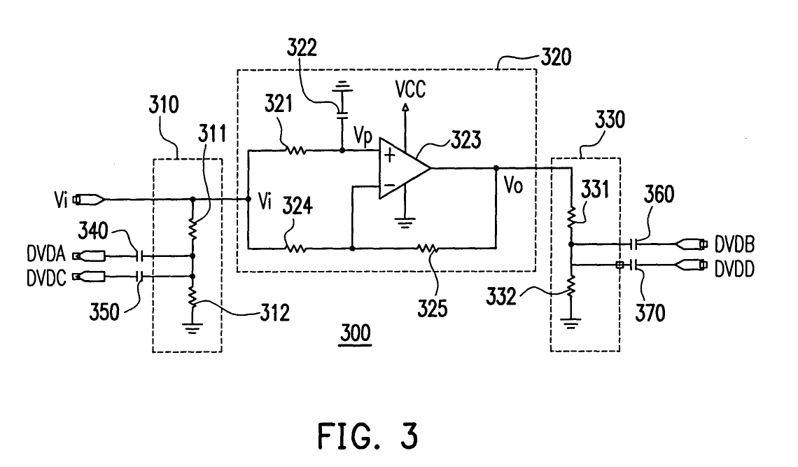

Referring to FIG. 3, a phase-shift RF-signal generating circuit is shown according to one preferred embodiment of this present invention. As depicted, the phase-shift RF-signal generating circuit 300 comprises: first signal potential divider 310, first high pass filter 340, second high pass filter 350, phase shifter 320, second signal potential divider 330, third high pass filter 340, and fourth high pass filter 350.

Therein, the first signal potential divider 310 is composed of resistor 311 and resistor 322 in series connection in order to obtain a voltage divided signal from 5 MHz variant digital signal Vi provided by testing device (not shown). For the testing device provides digital signals instead of a plurality of phase-shift RF signals, and for testing the analog circuit block of the DVD ROM chipset requires 75 mV signal swing, the testing device is set to output a digital square-wave input Vi possessing a signal swing of 600 mV.

The digital square-wave input signal Vi, voltage-divided by the first signal potential divider 310 feeds the first high pass filter 340 and the second high pass filter 350 composing a capacitor, so as to eliminate the dc signal along the divided signals as well as to generate first phase-shift RF signal DVDA and the second phase-shift RF signal DVDC having signal swing 75 mV.

On the other hand, the third phase-shift RF-signal DVDB and the fourth phase-shift RF-signal DVDD requiring signal swing 75 mV are to differ the first phase-shift RF signal DVDA and the second phase-shift RF signal DVDC by a phase difference of 40°. Hence, in order to obtain a phase-shifted output signal Vo differed from the input signal Vi, apply phase shifter 320 before obtaining DVDB and DVDD by applying the second signal potential divider 330 and the third and fourth high pass filter 340 and 350.

As depicted in FIG. 3, the phase shifter 320 receives digital input signal Vi from a testing device (not shown), and shift phase of Vi to output an output signal Vo by, for example, 40°, wherein the phase shifter 320 comprises an operating amplifier 323, a first resistor 321, a capacitor 322, a second resistor 324, and a third resistor 325. As to the connections, one end of the first resistor 321 couples to digital input signal Vi, the other end couples to the positive input terminal of the operating amplifier 323. Mean-while, one end of the capacitor 322 couples to the positive input terminal of the operating amplifier 323, and the other end couples to ground. Also, one end of the resistor 324 couples to the digital input signal Vi, and the other end couples to the negative input terminal of operating amplifier 323. As well as one end of the third resistor 325 couples to the negative input terminal of the operating amplifier 323, and the other end couples to the output terminal of the operating amplifier 323. Assuming the capacitance of capacitor 322 is C, and the resistance of the first resistor 321, the second resistor 324, and the third resistor 325 is R, then the phase-shift relation is expressed as follows.

The voltage Vp of the positive input terminal of the operating amplifier is:

$$Vp = Vi \cdot \{ \frac{1 + j ω C}{R + 1 \text{/} j ω C} \} = \frac{Vi}{1 + j ω CR} \qquad ( 1 )$$

In an ideal operating amplifier, the voltage of the negative input terminal of the operating amplifier 323 equals to that of the positive input terminal Vp, so that

$$\begin{matrix}Vo = [ \frac{Vp - Vi}{R} ] \cdot R + Vp = 2 Vp - Vi \cdot \frac{1 - j ω CR}{1 + j ω CR} \\ thus , & ( 2 ) \\ \frac{Vo}{Vi} = \frac{1 - j ω CR}{1 + j ω CR} = 1 ∠ - 2 {tan}^{- 1} ω CR & ( 3 )\end{matrix}$$

According to Eq. (3), the voltage gain of the phase shifter 320 is ONE, and the phase shift amount is determined by proper choice of R and C, so as to generate required phase shifted output signal Vo differed from input signal Vi.

Referring to FIG. 3 again, the resistors 331 and 332 in series compose the second signal potential divider 330 that is coupling to phase shifter 320 in order to receive phase-shifted signal Vo, as well as divide the shifted signal Vo so as to respectively feed third high pass filter 360 and fourth high pass filter 370 comprising of capacitors in order to eliminate dc signal, as well as to generate third and forth phase-shift RF signals DVDB and DVDD that have 75 mV signal swing. Therefore, the third and fourth phase-shift RF signals DVDB and DVDD differed from the first and second phase-shift RF signals DVDA and DVDC by a phase shift amount based on R C values.

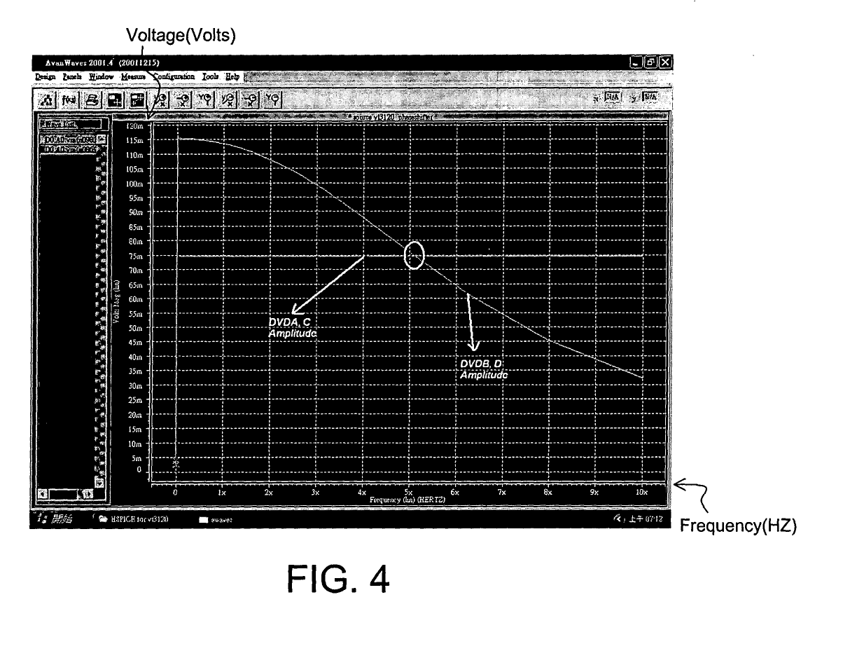

Referring to FIG. 4, a frequency response analysis diagram is illustrated herein based on the phase-shift RF-signal generating circuit in the present invention. The diagram is obtained from simulation of phase-shift RF-signal generating circuit 300 in FIG. 3 by Star-HSPICE 2001.4 simulator. According to FIG. 4, when phase-shift RF-signal generating circuit 300 in FIG. 3 receives a digital input signal Vi having p-p value of 600 mV and frequency of 5 MHz from testing device, output signals which are the first phase-shift RF signal DVDA, the second phase-shift RF signal DVDC, the third phase-shift RF-signal DVDB, and the fourth phase-shift RF signal DVDD are obtained with 75 mV p-p voltage and 5 MHz frequency. Whereas the first phase-shift RF signal DVDA and the second phase-shift RF signal DVDC differ from the third phase-shift RF signal DVDB and the fourth phase-shift RF signal DVDD by a phase shift.

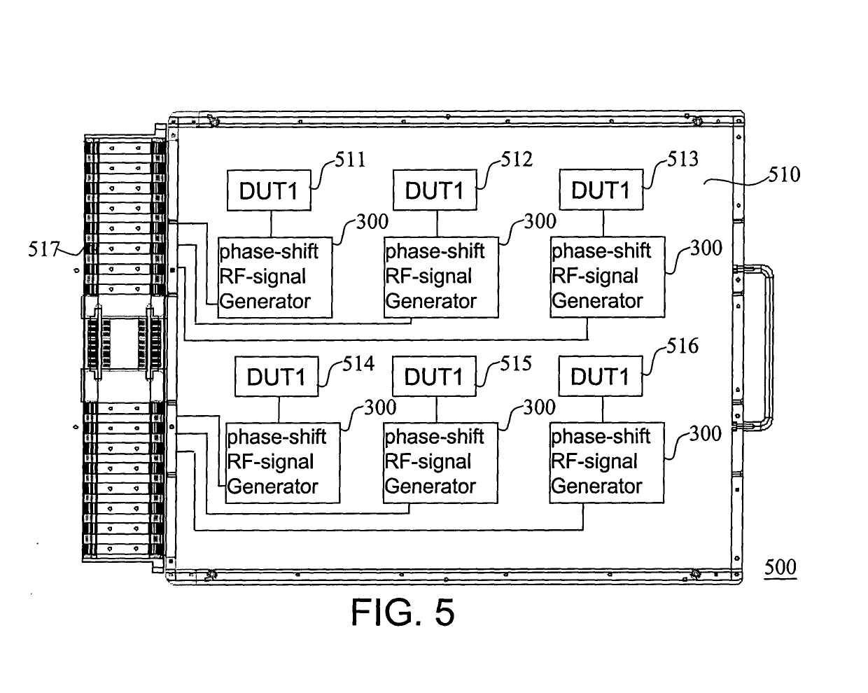

Referring to FIG. 5, a DVD ROM chipset testing board according to one preferred embodiment of this present invention is illustrated therein. This DVD ROM chipset HTOL testing board 500 is manufactured for HTOL testing in this present invention, so as to evaluate reliability of the DVD ROM chipset based on this High Temperature Operating Life testing.

According to the figure, this DVD ROM chipset HTOL testing board 500 comprises a testing board 510 and six of phase-shift RF-signal generating circuit 300, so as to test 6 DVD ROM chipset simultaneously. In order to collaborate between the first, the second, the third, and the fourth phase-shift RF signals DVDA, DVDC, DVDB, and DVDD, six chipset sockets were installed on testing board 520 in order to integrate the testing for DVD ROM chipsets entirely.

On the other hand, testing board 510 also provides connector 517 for connection to testing device (not shown) that provides digital input signal Vi for six of the phase-shift RF signal generating circuit 300. As a result, six of the phase-shift RF signal generating circuit 300 generates those RF signals, which are first phase-shift RF signal DVDA, second phase-shift RF signal DVDC, third phase-shift RF signal DVDB, and fourth phase-shift RF signal DVDD, based on digital input signal Vi provided by testing device. The DVD ROM chipsets under testing are plugged therein in chipset sockets 511, 512, 513, 514, 515, and 516, so as to take measurement of output signal TEO in order to diagnose the DVD ROM chipsets.

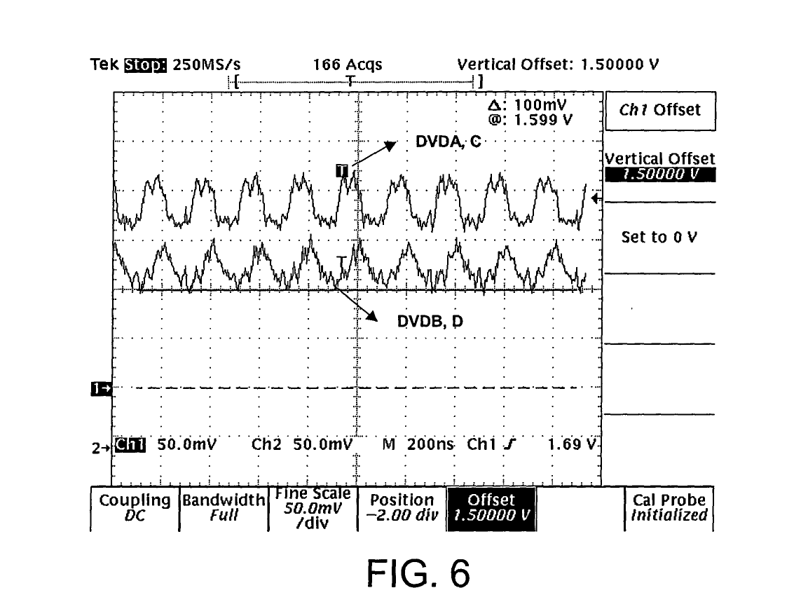

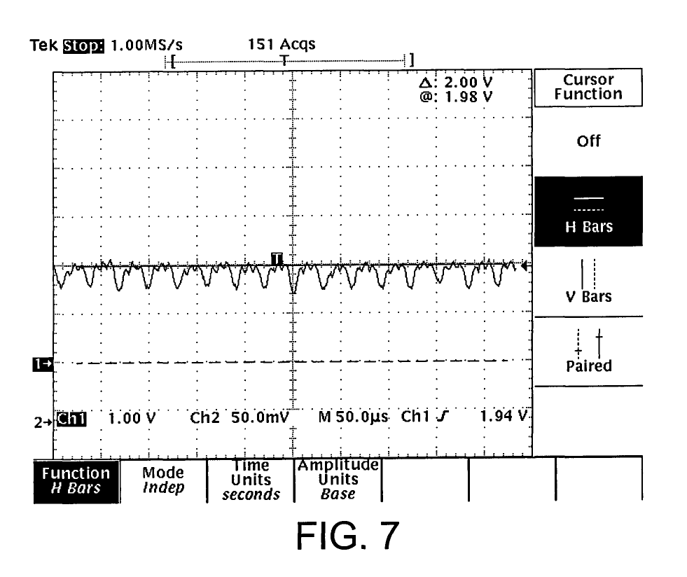

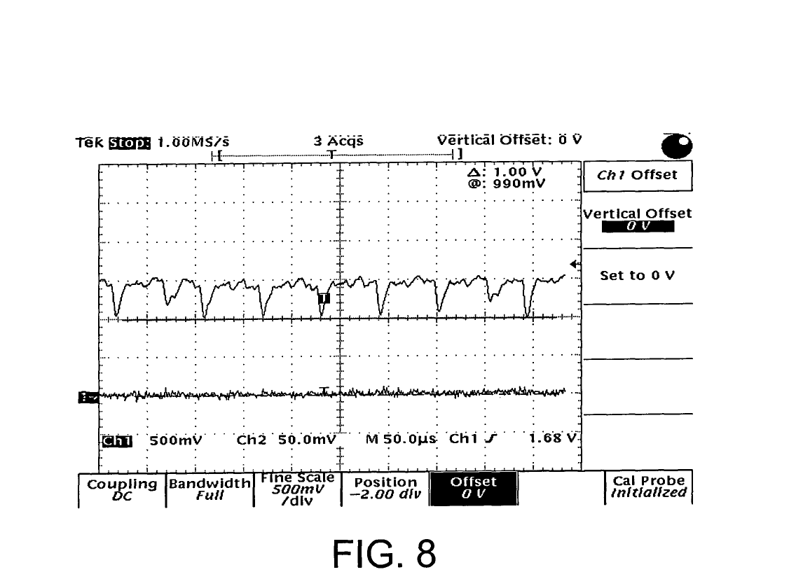

Also referring to FIG. 6, FIG. 7, and FIG. 8 all together. The experimental measurements of waveforms of first phase-shift RF signal DVDA, second phase-shift RF signal DVDC, third phase-shift RF signal DCDB, and fourth phase-shift RF signal DVDD are shown in FIG. 6. As to FIG. 7, a condition of first phase-shift RF signal DVDA and second phase-shift RF signal DVDC lead third phase-shift RF signal DVDB and fourth phase-shift RF signal DVDD by a phase difference is shown. Whereas in FIG. 8, a condition of first phase-shift RF signal DVDA and second phase-shift RF signal DVDC lag third phase-shift RF signal DVDB and fourth phase-shift RF signal DVDD by a phase difference is shown. According to FIG. 7 and FIG. 8, when first phase-shift RF signal DVDA and second phase-shift RF signal DVDC lead third phase-shift RF signal DVDB and fourth phase-shift RF signal DVDD by a phase shift, the voltage level of output signal TEO is between 1.5 V and 2.1 V. While on the contrary first phase-shift RF signal DVDA and second phase-shift RF signal DVDC lag third phase-shift RF signal DVDB and fourth phase-shift RF signal DVDD by a phase shift, the voltage level of output signal TEO locates between 0.8 V and 1.5 V. Hereby a properly working chipset is diagnosed.

Also notice that the first and second phase-shift RF signals generated by the phase-shift RF-signal generating circuit 300 in FIG. 3 lead the third and fourth phase-shift RF signals, thus when a condition of first and second phase-shift RF signals lagging the third and fourth phase-shift RF signals is observed, nothing has to be adjusted but to switch the two pairs of RF signal inputs feeding the DVD ROM chipset. In addition, although the DVD ROM chipset HTOL testing board 500 in one preferred embodiment of this present invention configures six chipset-sockets (i.e. 511, 512, 513, 514, 515 and 516) for simultaneous testing, the actual quantity of chipsets to be tested can be adjusted by sizing the testing board 510.

A phase-shift RF-signal generating method is concluded upon forgoing explanation, which provides four phase-shift RF signals for testing DVD ROM chipsets based on a frequency-variant digital input signal. This phase-shift RF-signal generating method comprises the following steps. Firstly, receive a digital input signal and divide the voltage of the signal and outputting the signal. Moreover, eliminate the dc signal composition and generate first and second phase-shift RF signals. Additionally, phase shift the digital input signal, receive the shifted digital input signal, and divide voltage of the shifted input signal. Ultimately, eliminate dc signal composition of the shifted and divided digital input signal, and generating the third and the fourth phase-shift RF signals.

Notice that the phase shift is 40°, the peak-to-peak signal swing is 75 mV and the frequency is 5 MHz for all the first, second, third, and fourth phase-shift RF signals.

In conclusion, this present invention provides a phase shift RF-signal generating circuit on DVD ROM testing board so as to be applied to testing device that only provides digital input signals in order to test DVD ROM chipsets under HTOL test.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A phase-shift RF-signal generating circuit, for generating a first phase-shift RF signal, a second phase-shift RF signal, a third phase-shift RF signal, and a fourth phase-shift RF signal for testing DVD ROM chipset based on a digital input signal that is frequency-variant, the phase-shift RF-signal generating circuit comprising:
a first signal potential divider, wherein the digital input signal is received, voltage divided, and output;
a first high pass filter, coupling to the first signal potential divider, wherein the dc composition of the digital input signal that is voltage divided is eliminated in order to generate the first phase-shift RF signal;
a second high pass filter, coupling to the first signal potential divider, wherein the dc composition of the digital input signal that is voltage divided is eliminated in order to generate the second phase-shift RF signal;
a phase shifter, wherein the digital input signal is received, shifted by a phase and output;
a second signal potential divider, coupling to the phase-shifter, wherein the digital input signal that is phase shifted is received, voltage divided, and output;
a third high pass filter, coupling to the second signal potential divider, wherein the dc composition of the digital input signal that is phase shifted and voltage divided is eliminated in order to generate the third phase-shift RF signal; and
a fourth high pass filter, coupling to the second signal potential divider, wherein the dc composition of the digital input signal that is phase shifted and voltage divided is eliminated in order to generate the fourth phase-shift RF signal.

2. The phase-shift RF-signal generating circuit as recited in claim 1, wherein each of the first signal potential divider and the second signal potential divider comprises two resistors in series.

3. The phase-shift RF-signal generating circuit as recited in claim 1, wherein each of the first high pass filter, the second high pass filter, the third high pass filter, and the fourth high pass filter comprises a capacitor.

4. The phase-shift RF-signal generating circuit as recited in claim 1, wherein the phase shifter comprises:
an operating amplifier, comprising a positive input terminal, a negative input terminal, and an output terminal, wherein the output terminal is to output the digital input signal that is phase shifted;
a first resistor, wherein one end of the first resistor couples to the digital input signal, and the other end couples to the positive input terminal;
a capacitor, wherein one end of the capacitor couples to the positive input terminal, and the other end is grounded;
a second resistor, wherein one end of the second resistor couples to the digital input signal, and the other end couples to the negative input terminal; and
a third resistor, wherein one end of the third resistor couples to the negative input terminal and the other end coupes to the output terminal.

5. The phase-shift RF-signal generating circuit as recited in claim 4, wherein the second resistor and the third resistor have identical resistance.

6. The phase-shift RF-signal generating circuit as recited in claim 1, wherein the phase shifter possess voltage gain of ONE, and phase shift of 40°.

7. The phase-shift RF-signal generating circuit as recited in claim 1, wherein the first phase-shift RF signal, the second phase-shift RF signal, the third phase-shift RF signal, and the fourth phase-shift RF signal have peak-to-peak value of 75 mV and frequency of 5 MHz.

8. A DVD ROM chipset testing board for undergoing high temperature operating life testing to a DVD ROM chipset, the DVD ROM chipset testing board comprises:
a testing base, having at least one chipset socket for plugging the DVD ROM chipset, and a connector for coupling to a testing device of the DVD ROM chipset, wherein the testing device provides a digital input signal varied with a frequency; and
a phase-shift RF-signal generating circuit, according to the digital input signal, for generating a first phase-shift RF signal, a second phase-shift RF signal, a third phase-shift RF signal, and a fourth phase-shift RF signal for testing the DVD ROM chipset, wherein the first phase-shift RF signal and the second phase-shift RF signal are in phase, and are differed by a phase shift from the third phase-shift RF signal and the fourth phase-shift RF signal.

9. The DVD ROM testing board as recited in claim 8, wherein the phase-shift RF signal generating circuit comprises:
a first signal potential divider, wherein the digital input signal is received, voltage divided, and output;
a first high pass filter, coupling to the first signal potential divider, wherein the dc composition of the digital input signal that is voltage divided is eliminated in order to generate the first phase-shift RF signal;
a second high pass filter, coupling to the first signal potential divider, wherein the dc composition of the digital input signal that is voltage divided is eliminated in order to generate the second phase-shift RF signal;
a phase shifter, wherein the digital input signal is received, shifted by a phase and output;
a second signal potential divider, coupling to the phase-shifter, wherein the digital input signal that is phase shifted is received, voltage divided, and output;
a third high pass filter, coupling to the second signal potential divider, wherein the dc composition of the digital input signal that is phase shifted and voltage divided is eliminated in order to generate the third phase-shift RF signal; and
a fourth high pass filter, coupling to the second signal potential divider, wherein the dc composition of the digital input signal that is phase shifted and voltage divided is eliminated in order to generate the fourth phase-shift RF signal.

10. The DVD ROM testing board as recited in claim 9, wherein each of the first signal potential divider and the second signal potential divider comprises two resistors in series.

11. The DVD ROM testing board as recited in claim 9, wherein each of the first high pass filter, the second high pass filter, the third high pass filter, and the fourth high pass filter comprises a capacitor.

12. The DVD ROM testing board as recited in claim 9 wherein the phase shifter comprises:
an operating amplifier, comprising a positive input terminal, a negative input terminal, and an output terminal, wherein the output terminal is to output the digital input signal that is phase shifted;
a first resistor, wherein one end of the first resistor couples to the digital input signal, and the other end couples to the positive input terminal;
a capacitor, wherein one end of the capacitor couples to the positive input terminal, and the other end is grounded;
a second resistor, wherein one end of the second resistor couples to the digital input signal, and the other end couples to the negative input terminal; and
a third resistor, wherein one end of the third resistor couples to the negative input terminal and the other end coupes to the output terminal.

13. The DVD ROM testing board as recited in claim 12, wherein the second resistor and the third resistor have identical resistance.

14. The DVD ROM testing board as recited in claim 9, wherein the phase shifter possesses voltage gain of 1, and phase shift of 40°.

15. The DVD ROM testing board as recited in claim 9, wherein the first phase-shift RF signal, the second phase-shift RF signal, the third phase-shift RF signal, and the fourth phase-shift RF signal have peak-to-peak value of 75 mV and frequency of 5 MHz.

16. A phase-shift RF-signal generating method for generating a first phase-shift RF signal, a second phase-shift RF signal, a third phase-shift RF signal, and a fourth phase-shift RF signal for testing DVD ROM chipset based on a digital input signal that is frequency-variant, the phase-shift RF-signal generating method comprising:
receiving, voltage dividing, and outputting the digital input signal;
eliminating the dc composition of the digital input signal that is voltage divided in order to generate the first phase-shift RF signal and the second phase-shift RF signal;
phase shifting and outputting the digital input signal;
receiving, voltage dividing, and outputting the digital input signal that is divided; and
eliminating the dc composition of the digital input signal that is phase shifted and voltage divided in order to generate the third phase-shift RF signal and the fourth phase-shift RF signal.

17. The phase-shift RF-signal generating method as recited in claim 16, wherein the phase shifted is 40°.

18. The phase-shift RF-signal generating method as recited in claim 16, wherein the first phase-shift RF signal, the second phase-shift RF signal, the third phase-shift RF signal, and the fourth phase-shift RF signal have peak-to-peak value of 75 mV and frequency of 5 MHz.
